(19) United States
(12) Patent Application Publication
(10) Pub. No.: US 2025/0237461 A1
(43) Pub. Date: Jul. 24, 2025

(54) INERT TRAINING FIREARMS AND METHODS OF MANUFACTURING THE SAME USING ADDITIVE MANUFACTURING PROCESSES

(71) Applicant: PE3D, LLC, Carrolton, GA (US)

(72) Inventor: Nolan Childers, Carrolton, GA (US)

(21) Appl. No.: 18/420,949

(22) Filed: Jan. 24, 2024

(51) Int. Cl. F41A 33/00; B33Y 50/00; B33Y 80/00; G06F 30/12

(52) U.S. Cl. CPC F41A 33/00; B33Y 80/00; G06F 30/12; B33Y 50/00

(57) ABSTRACT

Described herein are examples of a 3D training firearm and methods for manufacturing the same. In an example, the training firearm comprises an integral body of a first material that provides indicia of an inert training tool. The body comprises a barrel portion that can include a pair of grooves having, in some embodiments, a recess and a retention lip. A first groove can be located proximate a muzzle end of the barrel and a second groove can be located proximate a grip end of the barrel. A front sight and rear sight can also be provided, each made of at least a second material different from the first material and resembling the appearance of sights on a live firearm. Each sight can include a base portion such that the front sight can be positioned in the first groove and the rear sight can be positioned in the second groove.

### BACKGROUND

Additive manufacturing, more commonly known as 3D printing, is an approach to manufacturing objects by constructing such objects layer by layer from digital 3D models. In contrast to a traditional subtractive manufacturing process, which may involve cutting, machining, or otherwise removing material from a larger piece to achieve the desired shape, additive manufacturing builds up the final product incrementally.

The process typically begins with the creation of a digital 3D model using computer-aided design (CAD) software. This digital representation serves as a virtual blueprint for the physical object. The next step involves slicing the 3D model into thin, horizontal layers using specialized software. Each of these layers represents a cross-sectional slice of the final object.

Once the model is sliced, the 3D printer reads the data and proceeds to manufacture the object layer by layer. The choice of materials can vary and includes plastics, metals, ceramics, and even biological materials, depending on the specific 3D printing technology used. Common 3D printing technologies include fused deposition modeling (FDM), stereolithography (SLA), selective laser sintering (SLS), and more.

As each layer is deposited, it undergoes a process to ensure proper adhesion and structural integrity. This may involve curing, fusing, or solidifying the material, depending on the specific printing technology. The layering process continues until the entire physical object is produced.

The application of additive manufacturing spans various industries. For example, additive manufacturing can be used to create training firearms. Training firearms are imitation firearms specifically designed for educational and training purposes. These replicas closely mimic the size, weight, and handling characteristics of real firearms, providing a safe environment for individuals to practice and learn without the risks associated with live weapons. For example, training firearms are often used in scenario-based training exercises to simulate real-life situations and enhance decision-making skills. As a result, training firearms are used in various fields, including law enforcement, military, security, and civilian firearm safety courses.

Training firearms are designed to closely resemble actual firearms, both in terms of external appearance and weight. This realism contributes to a more authentic training experience. However, training firearms are incapable of firing live ammunition. They lack functional firing mechanisms, ensuring that they cannot discharge bullets.

One type of training firearm is sometimes referred to as a “non-gun replica.” Non-gun replicas are typically made from materials like rubber or plastic and they are completely inert and have no moving parts. As used herein, the terms “training firearm” and “non-gun replica” may be used interchangeably.

As a safety measure and to avoid confusion with functional firearms, 3D printed training firearms are typically printed using bright colored (e.g., blue, orange, or red) material that clearly identifies the inert training firearm as a training aid and ensures the training tools are not confused with live weapons. However, while such safety measures protect those training with the inert pistols, as well as other training participants and bystanders, they also introduce drawbacks. For example, by altering the color of 3D printed training firearms, a degree of realism is lacking in the user experience that can negatively influence a user's training.

As a result, a need exists for 3D printed training firearms, and methods for producing the same, that are visually distinct from a live firearm but simultaneously provide the user or trainee with a realistic training experience.

### SUMMARY

Descriptions herein include examples of 3D printed inert training firearms for use in training law enforcement and military personnel, for example. For purposes of this disclosure, 3D printing and additive manufacturing may be used interchangeably. Further, as used herein, “training firearm” or “training pistol” should be interpreted as an inert or non-functional/non-firing training device that shares some visual and/or physical similarities with a live or functional firearm but is designed for use in firearm training exercises. It should further be understood that while one or more embodiments set forth in this disclosure and the figures may include training “pistols,” the products and processes described herein apply to all types of training firearms, including but not limited to rifles and shotguns.

In an example, a 3D printed training firearm can include an integral body comprised of a first material of a first color indicative of an inert training firearm. The body can include a grip portion, a trigger portion, and a barrel portion. In one aspect, the barrel portion can have an upper surface extending from a muzzle end of the barrel portion to a grip end of the barrel portion. In some examples, the upper surface can include a first groove located proximate the muzzle end of the barrel portion and a second groove located proximate the grip end of the barrel portion.

In another aspect, a front sight and a rear sight are provided. The front sight can include a base portion positioned within the first groove of the barrel portion, and the rear sight can include a base portion positioned within the second groove of the barrel portion. In a further aspect, the front and rear sight can be printed using a second material different from the first material. For example, the second material can be of a second color resembling a color of a live firearm.

In another aspect, one or more of the first and second grooves can include a recess and a retention lip. In some examples, one or more of the front and rear sights can be configured for placement within the recess of the first and second grooves, respectively, such that the corresponding retention lip can overlap a portion of the sights' base portion.

In a further aspect, the first color of the first material can be blue, orange, red, or some other bright color that provides clear indicia to a training participant and/or any bystanders that the training firearm is inert and non-functional (i.e., incapable of firing a projectile). The second color, on the other hand, can be a color resembling the color of sights on a live firearm (e.g., black, grey, metallic, etc.). The front and rear sights can further include, in some examples, sight dots substantially similar in color and size to size dots of a live firearm. In further examples, the sight dots can comprise a phosphorescent element for use in low-light or dark environments.

A method is also provided for constructing a training firearm using an additive manufacturing process. The method can include providing a first computer-aided design (“CAD”) drawing a three-dimensional (“3D”) object that resembles a live firearm of a make and model. The object can comprise a barrel portion extending from a muzzle end to a grip end.

In one aspect, the CAD drawing can be edited such that an upper surface of the barrel portion can include a first groove at a location corresponding to the location of a front sight on the live firearm and a second groove at a location corresponding to the location of a rear sight on the live firearm.

In another aspect, the method can include providing a second CAD drawing of a front sight and a rear sight, wherein each of the front and rear sights can include a base portion configured to mate with the first and second grooves, respectively.

In a further aspect, the first and second CAD drawings, or a derivative thereof (e.g., a G-code print file) can be provided to one or more users for printing using a 3D printer. In some embodiments, the 3D object of the first CAD drawing can be printed using a material providing indicia that the 3D object is an inert or otherwise non-functional training device. In further embodiments, the sights of the second CAD drawing can be printed using a material resembling in appearance the sights of a live firearm. It should be noted that while the front and rear sights are provided in a single CAD drawing separate from the CAD drawing of the 3D object, each of these drawings (i.e., the 3D object, the front sight, and the rear sight) can be included in a single CAD file or multiple separate CAD files.

Both the foregoing general description and the following detailed description are exemplary and explanatory only and are not restrictive of the examples, as claimed.

### BRIEF DESCRIPTION OF THE DRAWINGS

The accompanying drawings, which are incorporated in and constitute a part of this disclosure, illustrate various embodiments and aspects of the present invention. In the drawings:

FIG. 1 is an illustration of a side view of example training firearm components;

FIG. 2 is an illustration of a perspective view of example training firearm components;

FIG. 3A is an illustration of a side view of example training firearm components;

FIG. 3B is an illustration of a side view of example training firearm components;

FIG. 3C is an illustration of a side view of example training firearm components;

FIG. 3D is an illustration of a side view of example training firearm components;

FIG. 4 is an illustration of a rear view of example training firearm components; and

FIG. 5 is a flow chart depicting steps in an example additive manufacturing process for printing training firearm components.

### DESCRIPTION OF THE EXAMPLES

Reference will now be made in detail to the present examples, including examples illustrated in the accompanying drawings. Wherever possible, the same reference numbers will be used throughout the drawings to refer to the same or like parts.

Described herein are examples of a 3D printed inert training firearm for training purposes, as well as method of manufacturing the same. In one aspect, the additive manufacturing of 3D printed training firearms involves a careful design and material selection process to ensure realism, durability, and compliance with all applicable legal requirements. For example, the design of a training firearm should closely approximate the size, weight, and ergonomics of the live or actual firearm it is intended to simulate. This would include elements of the training firearm such as its grip, trigger, and overall shape. However, whether required by law or for safety purposes, training firearms should be designed with clear indicators that they are inert, non-functional, and incapable of firing live ammunition. In some embodiments, this can involve incorporating permanently visible features to signal that the firearm cannot be used as a live weapon or to fire ammunition. For example, to prevent confusion with real firearms, training firearms can be printed using bright colored materials to clearly identify them as a training tool. Printing the training firearm with non-moving and/or non-functional components can further emphasize the inert nature of the object.

In another aspect, the material chosen for 3D printing should be durable enough to withstand handling during training exercises and not susceptible to one or more components breaking or failing in the course of use or when mishandled by an inexperienced trainee. In some examples, materials used to 3D print training firearms are high-strength plastics like ABS or nylon. In a further aspect, the weight of a training firearm as well as the distribution of weight along its body should be as close to the actual firearm as possible. In some examples, particular materials may be used, added, or omitted from areas within the printed object to yield a training firearm with a life-like feel and weight distribution.

In further aspects, training firearms can be 3D printed using a 3D printer and a print file. In some examples, the print file can be G-code generated from a computer-aided design (“CAD”) drawing of an inert training firearm, such as an inert training pistol. The CAD drawing can be created by one or more authors based on the dimensions of an actual firearm that the training firearm is intended to emulate. For example, the author(s) can use CAD software to construct the 3D geometry of the training firearm by drawing shapes, extruding and revolving the shapes, and using other tools to form the desired structure. In some embodiments, all dimensions, angles, and other physical parameters of the training firearm rendering can be adjusted until the 3D object closely resembles an actual firearm of a specific make and model. In alternative embodiments, a user can access one or more databases that store reference 3D CAD files associated with training firearms, each associated with a specific make and model of an actual firearm.

Regardless of the method by which a 3D CAD drawing for a training firearm is created or otherwise obtained, a user can use CAD software to alter the shape of the 3D object to remove, subtract, trim, cut, or otherwise edit one or more features of the 3D object. In some examples, a user may desire to remove one or more features of the 3D object in order to facilitate the future substitution of features of the training firearm with features more closely resembling real or live firearms. For example, in the case of a training pistol, the user can remove the otherwise integral front and rear sights from the barrel and/or upper surface of the training firearm. It should be understood, for purposes of this disclosure, that the term “barrel” is meant to refer generally to the longitudinal housing having an axis extending in a direction starting above the grip of the training firearm and extending toward the muzzle of the training firearm. For training firearms intended to mimic the appearance of live firearms of specific makes or models, the barrel may or may not be coupled with, or partially housed by, other components such as a slide, frame, and/or hammer. However, for the sake of clarity, the term “barrel” should be understood to include all such components, where applicable.

In further embodiments, in addition to removing the front and rear sights from the training pistol, the user can create notches in the upper surface of the training pistol (i.e., the upper surface of the barrel) just below the location of the front and rear sights. In one aspect, these notches located proximate to where the front and rear sights were previously located can be used to mount separately-manufactured sights. In another aspect, the separately manufactured sights can more closely resemble the sights of a real or live pistol. In this way, a trainee or user of the 3D training pistol receives a training experience that more closely mirrors the use of a real or live pistol. For example, when the user aims the training pistol at a target by aligning the pistol's sights with the target, the user perceives sights that more closely resemble the sights of a real or live pistol. In further examples, the separately manufactured sights can be sights printed on a 3D printer using a CAD file and/or a G-code file in a manner similar to the process described above with respect to the body of the training firearm. However, the material used to print the sights may be selected in order to provide the 3D printed sights with a more realistic appearance. For example, whereas the training pistol may be printed using a bright colored material (e.g., blue, orange, or red), the 3D printed sights may be printed using a black material or some other color that closely approximates the color of the actual firearm upon which the 3D training model is based. In further examples, the material used for the printed sights can be a plastic or a metal. In further embodiments, the sights may include one or more visual indicators to further aid the trainee and afford a more “life-like” training environment (i.e., a training environment that more closely mimics the use of a real or live firearm). For example, the sights may include opposing phosphorescent (or otherwise luminous) dots on either side of a rear dovetail sight and/or a single phosphorescent dot on the blade of a front sight. Alternatively, the dots on one or both of the rear and front sights can be white for increased visibility or some other color that approximates the color of the sights on the real or live firearm that the training firearms mimics. In embodiments where the visual indicators (e.g., dots on the sights) comprise a material of a different color from the remainder of the sights, the dots can be printed on or in the sights during the 3D printing of the sights or they can be added after the printing of the sights, for example, by affixing them to the sights or painting them on the sights.

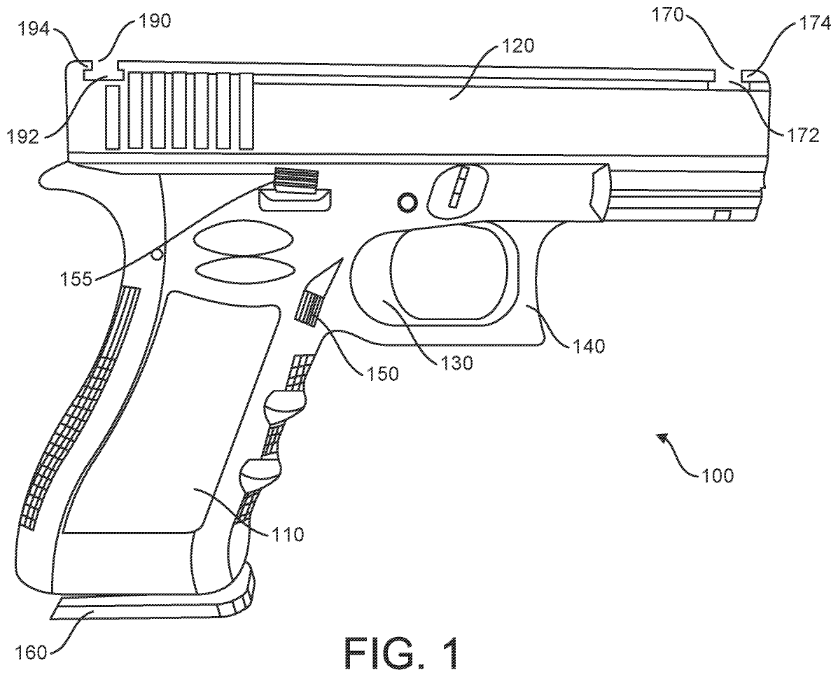

FIG. 1 is an illustration of a side view of an example training firearm 100 for use in training law enforcement or military personnel or other individuals. In one aspect, training firearm 100 can be 3D printed using a print file such as a G-code file, for example. In a further aspect, training firearm 100 can be comprised of one integral body having no moving parts. In some embodiments, training firearm 100 is composed of a plastic material such as ABS or nylon. In further embodiments, the material for printing training firearm 100 is selected, in part, based on its color. For example, training firearm 100 can be printed using a bright colored material, such as blue, orange, or red material. In such embodiments, the color of training firearm 100 can provide a clear visual indication that the object is a training tool and not a real or live (i.e., functioning) firearm capable of firing a projectile.

In one aspect, training firearm 100 can mimic the appearance of a live firearm of a particular make and model, exhibiting many of the same physical features albeit features that do not move or function. For example, training firearm 100 can be approximately the same size, shape, or weight of a semi-automatic pistol such as, for example, a GLOCK 19. In another aspect, training firearm 100 can include a grip 110, a barrel 120, a trigger 130, and a trigger guard 140. In further embodiments, training firearm 100 can include additional non-functioning features such as a magazine release button 150, a slide stop lever 155, and a magazine 160.

In another aspect, one or more portions of training firearm 100 can be omitted relative to a live firearm of a particular make and model. For example, where training firearm 100 is intended to approximate the appearance of a GLOCK 19, the front and rear sights can be omitted from training firearm 100. In further examples, training firearm 100 can comprise grooves or notches in barrel 120 at locations near or adjacent the usual location of the front and rear sights. In some examples, as depicted in FIG. 1, groove 170 can be located at the muzzle end of barrel 120 near the location of the front sight on a corresponding live pistol. Similarly, groove 190 can be located at the grip end of barrel 120 near the location of the rear sight on a corresponding live pistol. In further embodiments, groove 170 can comprise a recess 172 in the upper surface of the barrel 120 and a pair of opposing retention lips 174. Likewise, groove 190 can include a recess 192 and a pair of opposing retention lips 194.

In another aspect, the omission of the front and rear sights and the addition of grooves 170 and 190 can be made using a CAD program to alter or create a CAD drawing that otherwise resembles a corresponding live firearm. Further details regarding how the CAD drawing can be altered or created to omit the sights and create grooves 170 and 190 are discussed below. Because all of the components depicted in FIG. 1 are integral with the body of training firearm 100, training firearm can be created layer-by-layer in a single additive manufacturing session using a 3D printer and a print file (e.g., G-code file).

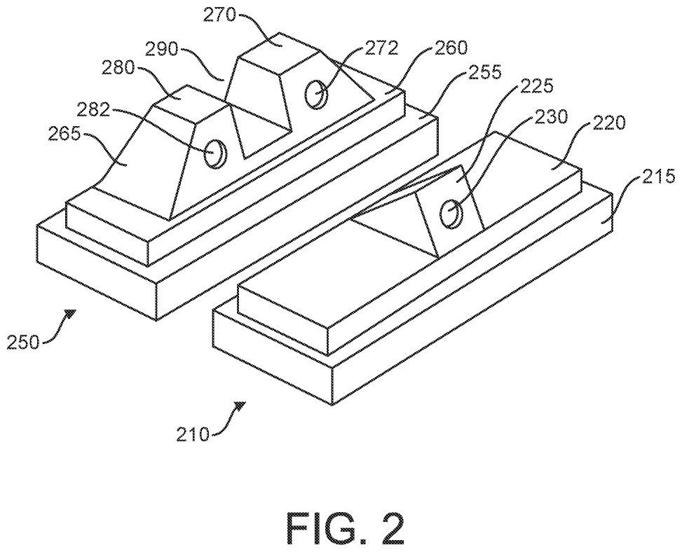

FIG. 2 depicts a perspective view of front sight 210 and rear sight 250. Front sight 210 and rear sight 250 can be manufactured apart from the 3D printing session used to construct training firearm 100. For example, front sight 210 and rear sight 250 can be 3D printed in a printing session independent of training firearm 100. Alternatively, front sight 210 and rear sight 250 can be manufacturing by any of a number of manufacturing processes, including machining, casting, injection molding, extruding, forging, or any other suitable manufacturing process.

Where front sight 210 and rear sight 250 are 3D printed a plastic similar to the plastic used to print training firearm 100 can be used. If an alternative manufacturing method is used, front sight 210 and rear sight 250 can be made of metal, a composite material, a plastic, or any other suitable material.

Importantly, and regardless of whether the sights are 3D printed or manufactured using some other process, the material can be selected to enhance the realism of the sites. For example, where the sites are 3D printed using a plastic, a plastic can be selected that is black or otherwise the same color as the live firearm that the training firearm seeks to mimic. Alternatively, the sights can be manufactured from a metal or other material that is the same, or substantially similar, to the sights found on a corresponding live firearm. In this way, a trainee using front sight 210 and rear sight 250 will experience a more realistic sight picture (i.e., the view of the sights from a user's perspective as he or she aligns the front and rear sights with a target) during training exercises.

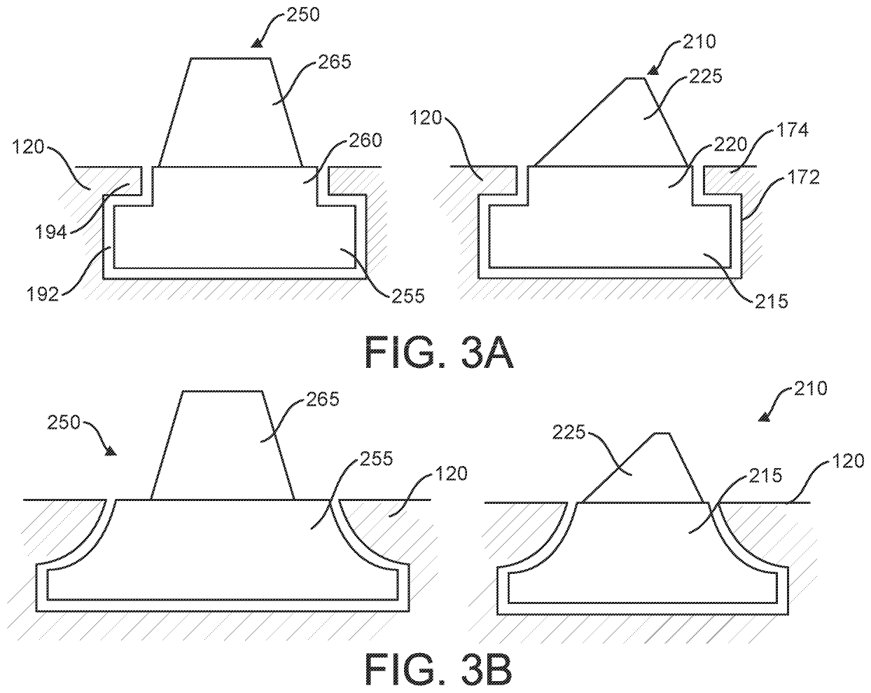

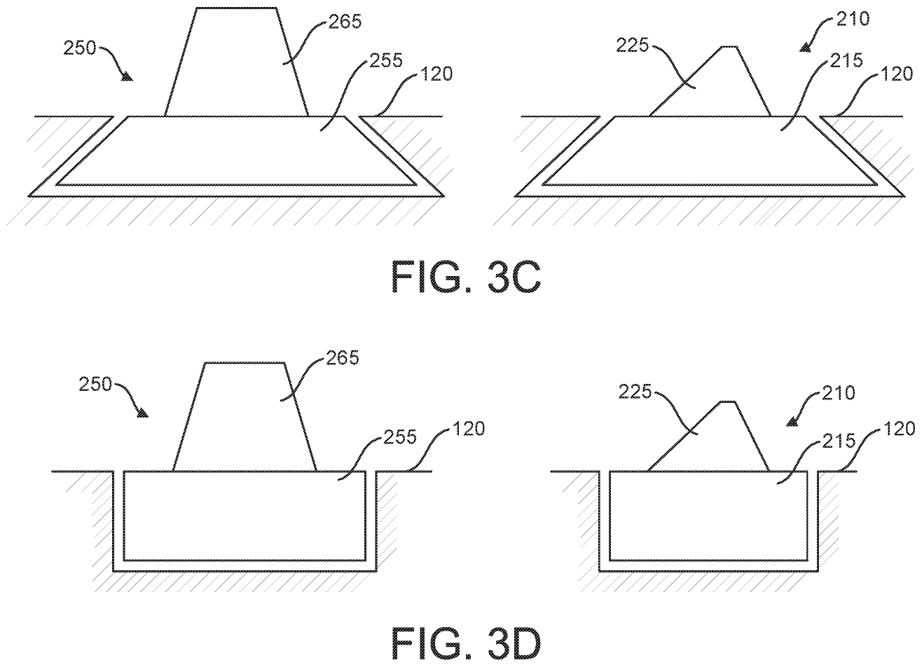

In one aspect, front sight 210 can include a base portion 215, a platform portion 220, and a blade portion 225. In one embodiment, all portions of front sight 210 are integral with respect to one another. In some embodiments, base portion 215 can be of a size and shape corresponding with recess 172 of groove 170 (depicted in FIG. 1) of training firearm 100. Base portion 215 can also be shaped such that retention lips 174 of groove 170 can extend over a portion of the upper surface of base portion 215. Further details regarding how front sight 210 can be located within, and retained by, groove 170 of training firearm 100 are discussed with respect to FIGS. 3A-D.

In further embodiments, platform portion 220 of front sight 210 can be located adjacent and atop base portion 215. Where base portion 215 of front sight 210 is located within groove 170, a front and rear surface of platform portion 220 can be positioned adjacent the lateral walls of retention lips 174, in some embodiments. In still further embodiments, where base portion 215 is located within groove 170, the upper surface of platform portion 220 can be coplanar or substantially coplanar with the upper surface of barrel 120.

In another aspect, blade portion 225 of front sight 210 can be located adjacent and atop platform portion 220. Where base portion 215 of front sight 210 is located within groove 170, blade portion 225 can be positioned in the approximate location of a front sight on a live firearm of the type training firearm 100 seeks to mimic.

In one aspect, rear sight 250 can include a base portion 255, a platform portion 260, and a dovetail portion 265. In one embodiment, all portions of rear sight 250 are integral with respect to one another. In some embodiments, base portion 255 can be of a size and shape corresponding with recess 192 of groove 190 (depicted in FIG. 1) of training firearm 100. Base portion 255 can also be shaped such that retention lips 194 of groove 190 can extend over a portion of the upper surface of base portion 255. Further details regarding how rear sight 250 can be located within, and retained by, groove 190 of training firearm 100 are discussed with respect to FIGS. 3A-D.

In further embodiments, platform portion 260 of rear sight 250 can be located adjacent and atop base portion 255. Where base portion 255 of rear sight 250 is located within groove 190, a front and rear surface of platform portion 260 can be positioned adjacent the lateral walls of retention lips 194, in some embodiments. In still further embodiments, where base portion 255 is located within groove 190, the upper surface of platform portion 260 can be coplanar or substantially coplanar with the upper surface of barrel 120.

In another aspect, dovetail portion 265 of rear sight 250 can be located adjacent and atop platform portion 260. Where base portion 255 of rear sight 250 is located within groove 190, dovetail portion 265 can be positioned in the approximate location of a rear sight on a live firearm of the type training firearm 100 seeks to mimic. In a further aspect, dovetail portion 265 can include a left (from a user's point of view) post 270 and a right (from a user's point of view) post 280 defining a gap or window 290 between them.

In some embodiments, blade portion 225 of front sight 210 can include a sight dot 230, and posts 270 and 280 of rear sight 250 can each include a sight dot 272, 282, respectively. In some examples, each sight dot can be defined by a recess within a surface of blade portion 225, post 270, and post 280, respectively, that faces a user during training. In other examples, the location of the sight dots may not be defined by a recess but is otherwise identified by a visual indicator located on blade portion 225, post 270, and post 280, respectively.

In a further aspect, each sight dot can be a phosphorescent (or otherwise luminous) element. Alternatively, the sight dots can be white or red for increased visibility or some other color that approximates the color of the front sight dot on the live firearm that training firearm 100 seeks to mimic. In embodiments where the sight dots comprise a material of a different color from the remainder of the sights, the sight dots can be 3D printed in the same printing session as front sight 210 and rear sight 250, respectively. In other embodiments, the sight dots can be added after the printing of front sight 210 or rear sight 250, for example, by affixing stickers to blade portion 225, post 270, and post 280, or painting the sight dots on blade portion 225, post 270, and post 275.

FIGS. 3A-D depict side views of embodiments of front sight 210 and rear sight 250 fitted within grooves 170 and 190, respectively, of training firearm 100. For example, FIG. 3A depicts a side view of front and rear sight embodiments substantially similar to those depicted in the perspective view of FIG. 2. In one example, the base portions 215 and 255, respectively, are substantially rectangular in cross section and cuboid in shape (i.e., a rectangular prism). In another example, platform portions 220 and 260, respectively, are similarly substantially rectangular in cross section and cuboid in shape. In further examples, platform portions 220 and 260 can have a smaller length and width than the base portions 215 and 255 to which they are attached and/or integrally formed.

In another aspect, blade 225 and dovetail 265 can have a smaller length and width at their base than the length and width of platform portions 220 and 260 to which they are attached and/or integrally formed. In some embodiments, while blade 225 and dovetail 265 can be any suitable shape and size for forming front and rear sights 210, 250, blade 225 and dovetail 265 are of a shape and size that substantially correspond to the blade and dovetail found on the live firearm that training firearm 100 seeks to mimic.

FIGS. 3B, 3C, and 3D depict side views of alternative embodiments of front and rear sights 210 and 250. In one aspect, while front and rear sights 210, 250 depicted in FIG. 2 and FIG. 3A include a base portion, a platform portion, and a blade or dovetail, respectively, the sights depicted in FIGS. 3B-D have only a base portion 215, 255 that is directly adjacent blade 225 or dovetail 265.

In another aspect, base portions 215, 255 of FIGS. 3B and 3C can be any suitable shape for positioning the front and rear sights within grooves 170 and 190, respectively. In some embodiments, the lateral walls of base portions 215, 225 extend outwards, either linearly, non-linearly, in a curve, or some combination thereof such that the sights can be slid into grooves 170 and 190, respectively, and retention lips 174, 194 can retain sights 210, 250.

In further embodiments, in addition to retention lips 174, 194 retaining sights 210, 250, the sights can be secured within grooves 170, 190 using other techniques such as gluing, soldering, or otherwise affixing the sights within their respective grooves. In some examples, where both the barrel 120 and one or both of sights 210, 250 are made of plastic or a plastic-containing composite, one or both sights can be melt-bonded within their respective grooves by melting an outer layer of the material comprising the sights and/or the grooves of training firearm 100.

In another embodiment, depicted in FIG. 3D, the lateral walls of base portions 215, 255 can extend downward substantially perpendicular to the upper surface of barrel 120. In such an embodiment, grooves 170 and 190 of firearm 100 may not include retention lips 174 and 194. Rather than using the retention lips to retain or partially retain sights 210 and 250, one or both sights can be glued, soldered, melt-bonded, or otherwise affixed within their respective groove. In further embodiments, the lateral walls of base portions 215, 255 can extend downward and narrow with respect to one another as they approach the lower surface of their respective groove.

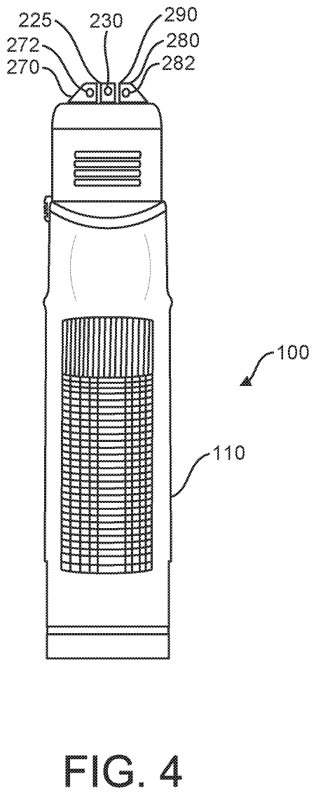

FIG. 4 depicts a rear view of firearm 100 (i.e., the view of training firearm 100 from the perspective of a user aiming the training tool at a target) after front sight 210 and rear sight 250 are positioned and/or affixed within grooves 170 and 190, respectively.

In one aspect, this view depicts the sight window seen by a user as they aim training firearm 100 at a target. In one embodiment, aiming training firearm 100 at a target involves centering blade 225 within gap 290 between left post 270 and right post 280, as well as vertically aligning sight dot 230 of blade 225 with sight dots 272 and 282 of posts 270 and 280, respectively.

In another aspect, while the body of training firearm 100, including but not limited to grip 110, barrel 120, trigger 130, and trigger guard 140 are all comprised of a bright material (e.g., blue, orange, or red) that provides clear visual indicators that the object is an inert training firearm as opposed to a real or live weapon, the front and rear sights 210, 250 are not only shaped substantially similar to the corresponding components of the firearm which training firearm 100 seeks to mimic, but the sights can also be a realistic color and can include realistic sight dots. As a result, in such embodiments, the sight window upon which the user/trainee is focused more closely mimics the sight window provided by a live firearm and the user can benefit from a more realistic training experience.

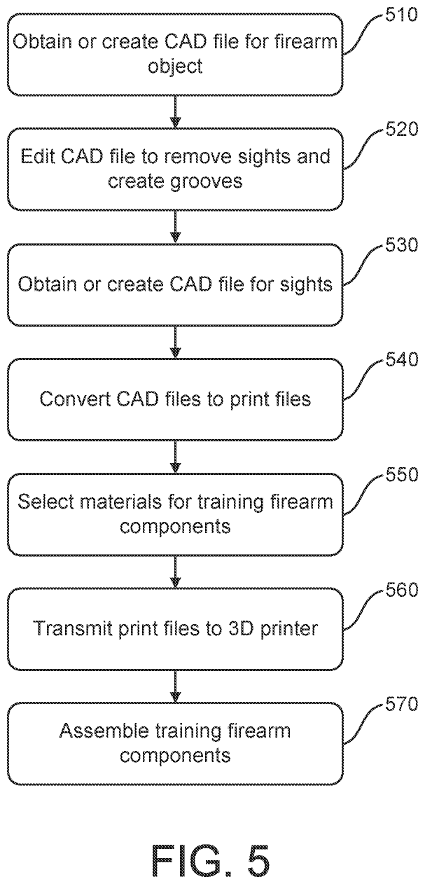

FIG. 5 depicts a flowchart including example steps in a process for manufacturing training firearm 100, in some embodiments. In step 510, a user of a computer (who could be but is not necessarily a user of training firearm 100) can obtain a CAD drawing of a firearm object. In some examples, the firearm object closely mimics the appearance of a live firearm of a particular make and model. In some embodiments, the user can create the firearm object using a CAD program. In other embodiments, the user can retrieve an existing firearm object from one or more databases.

At step 520, the user can edit the firearm object using a CAD program to remove, subtract, trim, cut, or otherwise edit one or more features of the firearm object. In some embodiments, the user can remove the front and rear sights from the CAD object. In alternative embodiments where the user creates the firearm object using the CAD program, the sights can simply be omitted. In another aspect, the user can create grooves 170 and 190 in the upper surface of barrel 120 assembly by removing portions of the barrel of the firearm object.

The manipulation of the firearm object within the CAD program can be accomplished using any of a number of techniques, or some combination thereof. For example, a user could use a Boolean subtraction operation to distinguish the sights from the remainder of the firearm object and then “subtract” the sights. Alternatively, the user could use any of a number of cutting or trimming tools available within the CAD program. In other embodiments, the user could use direct editing techniques in which specific surfaces and portions thereof are selected for removal.

At step 530, the user can obtain one or more CAD drawings of a front and a rear sight, each having a base portion having a shape and size corresponding approximately with the shape and size of grooves 170 and 190 of the firearm object formed in step 520. In some embodiments, the user can create the front and rear sights using the CAD program. In other embodiments, the user can retrieve existing front and rear sights from one or more databases.

In one aspect, the size and shape of blade 225 of front sight 210 and dovetail 265 (including posts 270 and 280) of rear sight 250 closely approximate the size and shape of the blade and dovetail of the live weapon that training firearm 100 seeks to mimic. In a further aspect, one or more of blade 225, post 270, and post 280 can be further manipulated to create recesses in their surface at the location of desired sight dots. Additional details regarding the sight dots are described above.

At step 540, the user can convert the CAD drawings of the manipulated firearm object, the front sight, and the rear sight to G-code files for use by a 3D printer. The G-code can contain, among other information, instructions for printing the firearm object, front sight, and rear sight in a layer-by-layer process. While “G-code” is used herein to describe a file type executable by a 3D printer, one of ordinary skill in the art understands that any appropriate file type that is executable by a 3D printer could be used.

At step 550, in one aspect, the user can select a material for printing the firearm object that is suitable for 3D printing a training firearm. For example, the user may select one or more high-strength plastics or composites like ABS or nylon, or some other suitable material. In further embodiments, the user can also select a color for the material that is appropriate for a training firearm. For example, the user can select a brightly colored material (e.g., blue, orange, or red) such that the printed training firearm will be clearly distinguishable from a live firearm even at a great distance or in poor visibility conditions.

In another aspect, the user can select one or more additional materials for printing the front and rear sights. Like the firearm object, the sights can be printed using one or more high-strength plastics like ABS or nylon. Alternatively, the sights can be printed using one or more metals, composites, or other suitable materials. Unlike the firearm object, however, rather than the user selecting a color for the sight material that provides a clear visual indication that the object is not a live firearm, the user can select a material and color for the sights that closely resembles the material and color of the front and rear sight of a live firearm which training firearm 100 seeks to mimic. In further embodiments, the user can also select a material and color for sight dots that closely resembles the corresponding live firearm.

At step 560, in some embodiments, the user can transmit the G-code print files for the firearm object, the front sight, and the rear sight to a 3D printer for printing. In some examples, the user's computer can be connected directly to the 3D printer. In other examples, the user can transmit the print files wirelessly to the 3D printer or to a server for storage. In such embodiments, the 3D printer and/or server can be in the same geographical location of the user's computer or one or both of the printer and server can be remotely located.

At step 570, after printing the body of training firearm 100, front sight 210, and rear sight 250, the user can position and affix the sights within corresponding grooves 170, 190 of training firearm 100. As described above, positioning and affixing the sights within their corresponding groove can optionally include gluing or soldering the sights in place, melt-bonding the sights in place, or otherwise affixing the base portions of the sights within the grooves of firearm 100.

In examples where a recess was formed in one or more of blade 225, post 270, and post 280 but a material was not used in printing to approximate realistic sight dots, or where printed training firearm 100 comprises no indication of sight dots, the user can apply sight dots to one or more of blade 225, post 270, and post 280 using stickers, paint, glue, or some other suitable material. In some embodiments, the material selected for the sight dots closely resembles the size, shape, and color of sight dots on a live firearm that training firearm 100 seeks to mimic.

Other examples of the disclosure will be apparent to those skilled in the art from consideration of the specification and practice of the examples disclosed herein. Though some of the described methods have been presented as a series of steps, it should be appreciated that one or more steps can occur simultaneously, in an overlapping fashion, or in a different order. The order of steps presented is only illustrative of the possibilities and those steps can be executed or performed in any suitable fashion. Moreover, the various features of the examples described here are not mutually exclusive. Rather any feature of any example described here can be incorporated into any other suitable example. Further, with respect to FIG. 5, while one or more steps may be performed by a “user,” it is understood that the described steps need not all be performed by a single individual. Rather, any one or more steps could be completed by a first individual, and any one or more remaining steps could be completed by one or more other individuals. Additionally, “user” in the context of obtaining, creating, or editing CAD drawings and/or G-code print files are not necessarily the same “users” as those who use the training firearm for firearm training purposes, though they could be. It is intended that the specification and examples be considered as illustrative only, with a true scope and spirit of the disclosure being indicated by the following claims.

What is claimed is:

1. A 3D printed training firearm, comprising:
a firearm body printed using a first material indicative of an inert training tool, including:
a grip portion;
a trigger portion; and
a barrel portion, the barrel portion having an upper surface, wherein the upper surface comprises a first groove at a muzzle end of the barrel portion and a second groove at a grip end of the barrel portion;
a front sight having a first base portion positioned within the first groove; and
a rear sight having a second base portion positioned within the second groove,
wherein the front and rear sight are printed using a second material resembling components of a live firearm.

2. The 3D printed training firearm of claim 1, wherein grip portion, trigger portion, and barrel portion are integral with the body.

3. The 3D printed training firearm of claim 1, wherein the firearm body is sized and shaped to resemble a make and a model of a live firearm.

4. The 3D printed training firearm of claim 1, the rear sight comprising a dovetail having first and second posts.

5. The 3D printed training firearm of claim 4, the front sight comprising a blade, wherein each of the blade, the first post, and the second post include a sight dot.

6. The 3D printed training firearm of claim 4, wherein each sight dot comprises a phosphorescent element.

7. The 3D printed training firearm of claim 1, wherein each of the first and second groove define a recess and a retention lip.

8. A 3D printed training firearm, the training firearm comprising:
a firearm body printed using a first material of a first color indicative of an inert training firearm, including:
a grip portion;
a trigger portion; and
a barrel portion, the barrel portion having an upper surface extending from a muzzle end of the barrel portion to a grip end of the barrel portion, wherein the upper surface comprises a first groove at the muzzle end and a second groove at the grip end; and
a front sight having a first base portion positioned within the first groove; and
a rear sight having a second base portion positioned within the second groove,
wherein the front and rear sight are printed using a second material of a second color substantially similar to a color of a live firearm.

9. The training firearm of claim 8, the first groove defining a first recess and a first retention lip, and the second groove defining a second recess and a second retention lip.

10. The training firearm of claim 9, the first base portion of the front sight is configured for placement within the first recess and the first retention lip overlaps a portion of the first base portion.

11. The training firearm of claim 9, the second base portion of the rear sight is configured for placement within the second recess and the second retention lip overlaps a portion of the second base portion.

12. The training firearm of claim 8, wherein the first color is blue, orange, or red.

13. The training firearm of claim 8, wherein the second color is black, grey, or metallic in appearance.

14. The training firearm of claim 8, wherein the front sight comprises a blade having a first sight dot, and the rear sight comprises a first and second post having a second and third sight dot, respectively.

15. A method for creating a 3D print file for making a training firearm using an additive manufacturing process, comprising:
providing a computer-aided design (“CAD”) drawing of a three-dimensional (“3D”) object, the 3D object resembling a live firearm of a make and a model and including a barrel portion;
editing the CAD drawing such that an upper surface of the barrel portion of the 3D object includes:
a first groove at a location of the 3D object corresponding to a front sight of the live firearm; and
a second groove at a location of the 3D object corresponding to a rear sight of the live firearm;
providing the CAD drawing, or a derivative thereof, to a user for 3D printing;
providing to the user a second CAD drawing, or a derivative thereof, of a front sight and a rear sight, each of the front and rear sights including a base portion intended to mate with the first and second grooves, respectively.

16. The method of claim 15, wherein the front sight includes a blade portion and the rear sight includes a dovetail portion.

17. The method of claim 16, wherein the derivative of either the CAD drawing or the second CAD drawing is a 3D print file.

18. The method of claim 16, wherein the 3D print file is a G-code print file.

19. The method of claim 15, wherein the CAD drawing and the second CAD drawing are included in a single master file and the master file, or a derivative thereof, is provided to the user.

20. The method of claim 15, wherein the first and second grooves each define a recess portion and a retention lip portion.
